(19) United States
(12) Patent Application Publication
(10) Pub. No.: US 2024/0090244 A1
(43) Pub. Date: Mar. 14, 2024

(54) OHMIC-CONTACT-GATED CARBON NANOTUBE TRANSISTORS, FABRICATING METHODS AND APPLICATIONS OF SAME

(71) Applicant: NORTHWESTERN UNIVERSITY, Evanston, IL (US)

(72) Inventors: Mark C. Hersam, Wilmette, IL (US); William A. Gaviria Rojas, Mountain View, CA (US); Megan E. Beck, Hillsboro, OR (US); Vinod K. Sangwan, Evanston, IL (US)

(21) Appl. No.: 18/270,891

(22) PCT Filed: Jan. 6, 2022
(86) PCT No.: PCT/US2022/011367

§ 371 Date: Jul. 5, 2023

Related U.S. Application Data
(60) Provisional application No. 63/135,795, filed on Jan. 11, 2021.

(51) Int. Cl. H10K 10/84; H10K 10/46; H10K 85/20

(52) U.S. Cl. CPC H10K 10/84; H10K 10/476; H10K 85/221

(57) ABSTRACT

One aspect of this invention relates to an ohmic-contact-gated transistor (OCGT), comprising a bottom gate electrode formed on a substrate; a first dielectric layer formed on the bottom gate electrode; a thin film formed of a semiconducting material on the first dielectric layer; a bottom contact formed on a part of the thin film; a second dielectric layer conformally grown on the bottom contact to result in a self-aligned dielectric extension from the bottom contact on the thin film; and a top contact formed on the second dielectric layer on the top of the bottom contact and fully overlapping with the dielectric extension to define a device channel in the thin film under the dielectric extension between the bottom contact and the top contact.

### CROSS-REFERENCE TO RELATED PATENT APPLICATION

This application claims priority to and the benefit of U.S. Provisional Application Ser. No. 63/135,795, filed Jan. 11, 2021, which is incorporated herein by reference in its entirety.

### STATEMENT AS TO RIGHTS UNDER FEDERALLY-SPONSORED RESEARCH

This invention was made with government support under 1720139 awarded by the National Science Foundation. The government has certain rights in the invention.

### FIELD OF THE INVENTION

The present invention relates generally to electronics, and more particularly to ohmic-contact-gated carbon nanotube transistors, fabricating methods and applications of the same.

### BACKGROUND OF THE INVENTION

The background description provided herein is for the purpose of generally presenting the context of the invention. The subject matter discussed in the background of the invention section should not be assumed to be prior art merely as a result of its mention in the background of the invention section. Similarly, a problem mentioned in the background of the invention section or associated with the subject matter of the background of the invention section should not be assumed to have been previously recognized in the prior art. The subject matter in the background of the invention section merely represents different approaches, which in and of themselves may also be inventions. Work of the presently named inventors, to the extent it is described in the background of the invention section, as well as aspects of the description that may not otherwise qualify as prior art at the time of filing, are neither expressly nor impliedly admitted as prior art against the invention.

The advent of robust artificial learning software has enabled the extraction of actionable insights from empirical and noisy sensor data available via personalized electronic gadgets. Significantly improved computation power, communication bandwidth, and efficiency of these software classifiers have led to unprecedented levels of data collection from sensing hardware, such as wearable and Internet of Things (IoT) devices. Owing to this growing demand for ubiquitous monitoring and data collection, tailored sensing technologies are being developed for specific applications. One of these emerging applications is flexible electronic sensors, often used for sensing complex biological signals along bendable and moving surfaces. The use of conventional rigid semiconductors for these applications requires expensive processing, which limits their impact and integration. As a result, solution-processed semiconductors are sought for these applications due to their intrinsic mechanical flexibility and compatibility with low-cost additive manufacturing methods. A critical component in these sensing applications is the small-signal amplifier, which increases the signal amplitude and drives subsequent analog-to-digital converters (ADCs). However, the utility of amplifiers based on solution-processed semiconductors within practical sensing systems is limited by their low output currents and transistor scaling limitations. Therefore, high-performance analog amplifiers at scaled transistor dimensions must be realized to fully exploit the potential of solution-processed semiconductors in emerging flexible electronics.

Therefore, a heretofore unaddressed need exists in the art to address the aforementioned deficiencies and inadequacies.

### SUMMARY OF THE INVENTION

One of the objectives of this invention is to provide ohmic-contact-gated transistors (OCGTs) based on solution-processed semiconducting single-walled carbon nanotubes that enable high-gain analog amplifiers for sensing extremely weak physiological signals. To achieve this goal, the device design provides output current saturation in the short-channel limit without compromising output current drive. The resulting ohmic-contact-gated transistors are integrated in common-source amplifiers to concurrently achieve the highest width-normalized output current (about 30 μA·μm⁻¹) and length-scaled signal gain (about 230 μm⁻¹) to date for solution-processed semiconductors. The utility of these amplifiers for emerging sensing technologies is demonstrated by the amplification of complex millivolt-scale analog biological signals, including the outputs of electromyography, photoplethysmogram, and accelerometer sensors. Since the ohmic-contact-gated transistor design is compatible with other semiconducting materials, this invention establishes a general route to high-performance, solution-processed analog electronics.

In one aspect of this invention, the OCGT comprises a bottom gate electrode formed on a substrate; a first dielectric layer formed on the bottom gate electrode; a thin film formed of a semiconducting material on the first dielectric layer; a bottom contact formed on a part of the thin film; a second dielectric layer conformally grown on the bottom contact to result in a self-aligned dielectric extension from the bottom contact on the thin film; and a top contact formed on the second dielectric layer on the top of the bottom contact and fully overlapping with the dielectric extension to define a device channel in the thin film under the dielectric extension between the bottom contact and the top contact.

In one embodiment, the substrate comprises an undoped Si wafer.

In one embodiment, the semiconducting material comprises a solution-processed semiconducting material.

In one embodiment, the semiconducting material comprises solution-processed semiconducting single-walled carbon nanotubes (SWCNTs).

In one embodiment, the thin film comprises an SWCNT random network with about 99.9% semiconducting purity.

In one embodiment, the thin film comprises an SWCNT random network with a linear density of about 40 CNTs·μm⁻¹.

In one embodiment, the semiconducting material comprises MoS₂, MoSe₂, WS₂, WSe₂, InSe, GaTe, black phosphorus (BP), or related solution-processed semiconducting materials including organic semiconductor and inorganic metal-oxides.

In one embodiment, the bottom gate electrode, the bottom contact and the top contact are formed of the same conductive material or different conductive materials.

In one embodiment, each of the bottom gate electrode, the bottom contact and the top contact is formed of palladium (Pd), gold (Au), aluminum (Al), titanium (Ti), nickel (Ni), chromium (Cr), or other conductive materials including transparent indium tin oxides.

In one embodiment, the first dielectric layer and the second dielectric layer comprise a same dielectric material or different dielectric materials.

In one embodiment, each of the first dielectric layer and the second dielectric layer is formed of HfO₂, Al₂O₃, ZrO₂, ZnO, SiO₂, or dielectrics including alumina, hafnia, or zirconia and organic dielectric films grown by conformal molecular layer deposition.

In one embodiment, the second dielectric layer is a thin high-k dielectric layer formed of HfO₂ with a thickness of about 12 nm, k being a dielectric constant, and each of the bottom contact and the top contact is formed of an ohmic contact metal including Pd, for optimal short-channel performance of the SWCNT channel.

In one embodiment, an overlap region of the dielectric extension with the top contact determines a channel length (L) and creates a secondary gate that is shorted to the top contact.

In one embodiment, the OCGT geometry utilizes ohmic contacts with a short-channel length to achieve contact-gating with superior device performance.

In one embodiment, the OCGTs intrinsically mitigate short-channel (i.e., L<300 nm) effects by demonstrating an OCGT-based common-source amplifier.

In one embodiment, a signal gain of the OCGT-based common-source amplifier is quantified by applying a small input signal at the gate input that produces an inverted output signal.

In one embodiment, the OCGT is used in a common-source amplifier to attain the highest width-normalized output current and length-scaled signal gain to date for solution-processed semiconductors.

In one embodiment, the OCGT is characterized with exceptionally low width-normalized output conductance while maintaining high width-normalized output current levels.

In one embodiment, the use of ultrahigh purity semiconducting SWCNTs and ultrathin high-k dielectric layers provides improved electrostatic control of the channel, resulting in unipolar p-type transport with a simultaneously high Iₒₙ/I_{off} ratio, high output current, and negligible leakage current despite the short length of the channel.

In one embodiment, the SWCNT OCGTs achieves output current saturation concurrently with high output currents despite the short channel length.

In one embodiment, the design of the OCGT enables unprecedented levels of output current saturation in the short-channel limit for solution-processed semiconductors without compromising output current drive.

Another aspect of the invention relates to a circuit comprising at least one OCGT as disclosed above.

Yet another aspect of the invention relates to a device comprising at least one OCGT as disclosed above.

A further aspect of the invention relates to a method for fabricating an OCGT. The method comprises forming a bottom gate electrode on a substrate; forming a first dielectric layer on the bottom gate electrode; forming a thin film a semiconducting material on the first dielectric layer; forming a bottom contact on a part of the thin film; conformally growing a second dielectric layer on the bottom contact to result in a self-aligned dielectric extension from the bottom contact on the thin film; and forming a top contact on the second dielectric layer on the top of the bottom contact and fully overlapping with the dielectric extension to define a device channel in the thin film under the dielectric extension between the bottom contact and the top contact.

In one embodiment, said forming the thin film is performed by chemical vapor deposition (CVD), mechanical exfoliation, metal-organic chemical vapor deposition (MOCVD), or atomic layer deposition (ALD).

In one embodiment, the semiconducting material comprises a solution-processed semiconducting material.

In one embodiment, the semiconducting material comprises solution-processed semiconducting SWCNTs with about 99.9% semiconducting purity.

In one embodiment, the semiconducting material comprises MoS₂, MoSe₂, WS₂, WSe₂, InSe, GaTe, black phosphorus (BP), or related solution-processed semiconducting materials including organic semiconductor and inorganic metal-oxides.

In one embodiment, said forming the first dielectric layer is performed by photolithography and directional metal evaporation.

In one embodiment, said growing the second dielectric layer is performed with an undercut profile of negative photoresist combined with directional metal evaporation and conformal ALD of a dielectric oxide resulting in the self-aligned dielectric extension.

In one embodiment, the top contact electrode is patterned using photolithography and directional metal evaporation such that it fully overlaps the dielectric extending from the bottom contact.

In one embodiment, the bottom gate electrode, the bottom contact and the top contact are formed of the same conductive material or different conductive materials.

In one embodiment, each of the bottom gate electrode, the bottom contact and the top contact is formed of Pd, Au, Al, Ti, Ni, Cr, or other conductive materials including transparent indium tin oxides.

In one embodiment, the first dielectric layer and the second dielectric layer comprise a same dielectric material or different dielectric materials.

In one embodiment, each of the first dielectric layer and the second dielectric layer is formed of HfO₂, Al₂O₃, ZrO₂, ZnO, SiO₂, or dielectrics including alumina, hafnia, or zirconia and organic dielectric films grown by conformal molecular layer deposition.

These and other aspects of the present invention will become apparent from the following description of the preferred embodiment taken in conjunction with the following drawings, although variations and modifications therein may be affected without departing from the spirit and scope of the novel concepts of the invention.

### BRIEF DESCRIPTION OF THE DRAWINGS

The accompanying drawings illustrate one or more embodiments of the invention and together with the written description, serve to explain the principles of the invention. Wherever possible, the same reference numbers are used throughout the drawings to refer to the same or like elements of an embodiment.

FIG. 1 shows SWCNT OCGT fabrication processes according to embodiments of the invention. Panel a: Overview of OCGT fabrication using conventional photolithography. (1) A layer of semiconducting SWCNTs is placed on top of a bottom gate structure. (2) Negative photolithography and directional metal evaporation are used to deposit the bottom contact electrode. (3) A dielectric layer is conformally grown using ALD. (4) The bottom contact electrode with a dielectric extension is defined following liftoff. (5) The overlapping top contact electrode is deposited using conventional photolithography and directional metal evaporation. Panel b: Optical micrograph of multiple (left, 200 μm scale bar) and a single (right, 50 μm scale bar) OCGT device. Panel c: Schematic of an OCGT device, highlighting the relative positions of the contact electrodes and the definition of the channel length (L) by the dielectric extension. Panel d: (Left) Layered schematic of the fabricated SWCNT OCGT device using 12 nm HfO₂ dielectric layers, Pd ohmic contacts, and a SWCNT random network with ultrahigh (i.e., 99.9%) semiconducting purity. (Right) AFM image of the SWCNT network with a linear density of ˜40 CNTs·μm⁻¹ (500 nm scale bar).

FIG. 2 shows the performance of the SWCNT OCGT for two modes of operation according to embodiments of the invention. Panels a-b: Linear (panel a) and log-linear (panel b) transfer characteristic (I_{DS}−V_{GS}) where V_{DS} is varied from −0.5 V to −2 V in −0.25 V steps. Panel c: Linear output characteristic (I_{DS}−V_{DS}) where V_{GS} is varied from 0 V to −4 V in −0.5 V steps. These transfer and output characteristic results are shown for OCGTs operating in two modes: with their top contact at V_{DD} (left) and ground (right). Panel d: Log-linear behavior for width-normalized transconductance gₘ/W (left) and width-normalized output conductance gₒ/W (right) at V_{DS}=−2 V and V_{GS}=−1V, respectively, when the top contact is at V_{DD} (red) and ground (blue).

FIG. 3 shows the high performance common-source amplifiers using SWCNT OCGTs according to embodiments of the invention. Panel b: Overview of common signal acquisition systems, where sensors acquire analog signals (red) that are amplified (yellow), digitized (green), and processed digitally (blue). Panel b: Circuit diagram for the SWCNT OCGT-based common-source amplifier, where a small input signal (V_{IN}) is amplified (V_{OUT}). Panel c: Characterization of the SWCNT OCGT amplifier, where the signal gain (V_{OUT}/V_{IN}) of a small sinusoidal signal (top) changes from ˜5 (middle) to ˜68 (bottom) based on the top contact bias. Panel d: Comparison of width-normalized output current (I_{DS}/W) and length-scaled signal gain (Gain/L) for the best previously reported solution-processed amplifiers. This work (red star) outperforms the current state-of-the-art by over an order of magnitude in both metrics.

FIG. 4 shows the amplification of sensor signals using OCGT-based amplifiers according to embodiments of the invention. Panels a-c: Characterization of signal gain for complex analog signals using SWCNT OCGT-based common-source amplifiers. The input (top) and output (bottom) voltages are shown for the amplification of signals from sensors common in medical and IoT devices, including an electromyography sensor (panel a), a photoplethysmogram sensor (panel b), and an accelerometer (panel c). The DC offsets of the signals presented are modified for improved clarity.

FIG. 5 shows characterization of dielectric extension according to embodiments of the invention. Panel a: AFM image of a dielectric extension following photolithography, metal evaporation, ALD growth, and liftoff. The blue line highlights the location of an AFM profile from (1) the metal-dielectric stack to (2) the substrate (1 μm scale bar). Panel b: AFM thickness profile for the blue line in a. The length and thickness of the dielectric extension are approximately 280 nm and 12 nm, respectively.

FIG. 6 shows histogram of SWCNT OCGT Log(Iₒₙ/I_{off}) performance according to embodiments of the invention. Panels a-b: Histogram of Log(Iₒₙ/I_{off}) values for (panel a) V_{DS}=−0.5 V and (panel b) V_{DS}=−2 V. These characterization results are shown for 67 OCGT devices when the top contact is at V_{DD} (red) and ground (blue).

FIG. 7 shows histogram of SWCNT OCGT Iₒₙ/W performance according to embodiments of the invention. Panels a-b: Histogram of width-normalized on-current (Iₒₙ/W) values for (panel a) V_{DS}=−0.5 V and (panel b) V_{DS}=−2 V. These characterization results are shown for 67 OCGT devices when the top contact is at V_{DD} (red) and ground (blue).

FIG. 8 shows histogram of SWCNT OCGT I_{DS,max}/W performance according to embodiments of the invention. Histogram of maximum width-normalized output current (I_{DS,max}/W) values for V_{GS}=−4 V. These characterization results are shown for 67 OCGT devices when the top contact is at V_{DD} (red) and ground (blue).

FIG. 9 shows histogram of SWCNT OCGT gₒ/W and gₘ/W performance according to embodiments of the invention. Panel a: Histogram of width-normalized transconductance (gₘ/W) values at V_{DS}=−2 V. Panel b: Histogram of width-normalized output conductance (gₒ/W) values at V_{GS}=−1 V. The logarithmic values are given for improved clarity. These characterization results are shown for 67 OCGT devices when the top contact is at V_{DD} (red) and ground (blue).

FIG. 10 shows SWCNT OCGT gₘ/W characterization according to embodiments of the invention. Log-linear behavior for width-normalized transconductance (gₘ/W) when V_{DS} is varied from −0.5 V to −2 V in −0.25 V steps. These characterization results are shown for a representative OCGT device when the top contact is at V_{DD} (left) and ground (right).

FIG. 11 shows SWCNT OCGT gₒ/W characterization according to embodiments of the invention. Log-linear behavior for width-normalized output conductance (gₒ/W) when V_{GS} is varied from −0.5 V to −4 V in −0.5 V steps. These characterization results are shown for a representative OCGT device when the top contact is at V_{DD} (left) and ground (right).

FIG. 12 shows gate leakage characteristics of SWCNT OCGTs according to embodiments of the invention. Gate leakage current versus gate voltage of a SWCNT OCGT with top or bottom electrode grounded.

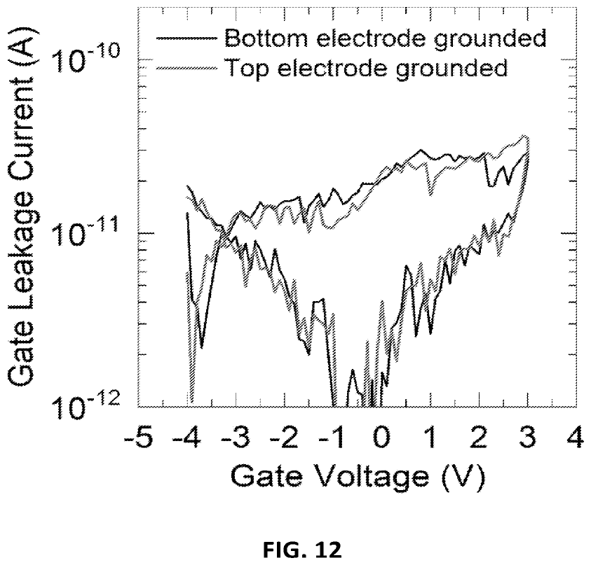

FIG. 13 shows a frequency response of a common-source amplifier using SWCNT OCGTs according to embodiments of the invention. Log-log plot of the gain of the input sinusoidal signal (peak-to-peak V_{IN}=10 mV) versus frequency using V_{DS}=−2 V. Unity gain occurs at 20 kHz.

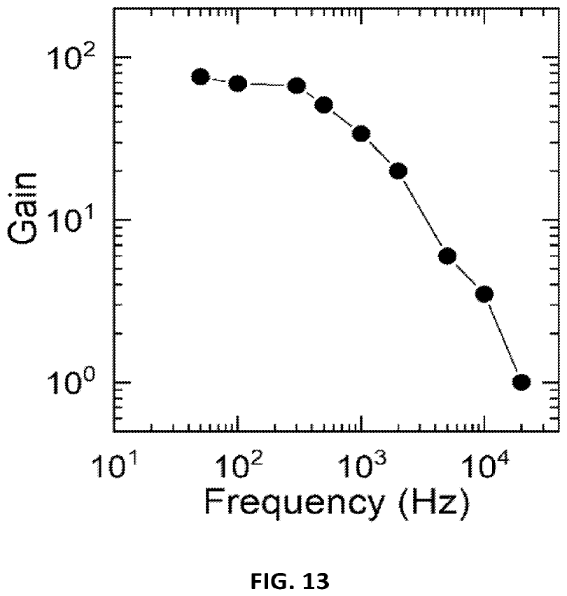

### DETAILED DESCRIPTION OF THE INVENTION

The invention will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this specification will be thorough and complete, and will fully convey the scope of the invention to those skilled in the art. Like reference numerals refer to like elements throughout.

The terms used in this specification generally have their ordinary meanings in the art, within the context of the invention, and in the specific context where each term is used. Certain terms that are used to describe the invention are discussed below, or elsewhere in the specification, to provide additional guidance to the practitioner regarding the description of the invention. For convenience, certain terms may be highlighted, for example using italics and/or quotation marks. The use of highlighting has no influence on the scope and meaning of a term; the scope and meaning of a term are the same, in the same context, whether or not it is highlighted. It will be appreciated that same thing can be said in more than one way. Consequently, alternative language and synonyms may be used for any one or more of the terms discussed herein, nor is any special significance to be placed upon whether or not a term is elaborated or discussed herein. Synonyms for certain terms are provided. A recital of one or more synonyms does not exclude the use of other synonyms. The use of examples anywhere in this specification including examples of any terms discussed herein is illustrative only, and in no way limits the scope and meaning of the invention or of any exemplified term. Likewise, the invention is not limited to various embodiments given in this specification.

It will be understood that, as used in the description herein and throughout the claims that follow, the meaning of “a”, “an”, and “the” includes plural reference unless the context clearly dictates otherwise. Also, it will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the invention.

Furthermore, relative terms, such as “lower” or “bottom” and “upper” or “top,” may be used herein to describe one element's relationship to another element as illustrated in the figures. It will be understood that relative terms are intended to encompass different orientations of the device in addition to the orientation depicted in the figures. For example, if the device in one of the figures. is turned over, elements described as being on the “lower” side of other elements would then be oriented on “upper” sides of the other elements. The exemplary term “lower”, can, therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

It will be further understood that the terms “comprises” and/or “comprising,” or “includes” and/or “including” or “has” and/or “having”, or “carry” and/or “carrying,” or “contain” and/or “containing,” or “involve” and/or “involving, and the like are to be open-ended, i.e., to mean including but not limited to. When used in this specification, they specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this specification, and will not be interpreted in an idealized or overly formal sense unless expressly so defined herein.

As used in this specification, “around”, “about”, “approximately” or “substantially” shall generally mean within 20 percent, preferably within 10 percent, and more preferably within 5 percent of a given value or range. Numerical quantities given herein are approximate, meaning that the term “around”, “about”, “approximately” or “substantially” can be inferred if not expressly stated.

As used in this specification, the phrase “at least one of A, B, and C” should be construed to mean a logical (A or B or C), using a non-exclusive logical OR. As used herein, the term “and/or” includes any and all combinations of one or more of the associated listed items.

The description below is merely illustrative in nature and is in no way intended to limit the invention, its application, or uses. The broad teachings of the invention can be implemented in a variety of forms. Therefore, while this invention includes particular examples, the true scope of the invention should not be so limited since other modifications will become apparent upon a study of the drawings, the specification, and the following claims. For purposes of clarity, the same reference numbers will be used in the drawings to identify similar elements. It should be understood that one or more steps within a method may be executed in a different order (or concurrently) without altering the principles of the invention.

The growing demand for ubiquitous data collection has driven the development of sensing technologies based on flexible electronics. As a result, solution-processed semiconductors have been widely employed due to their mechanical flexibility and compatibility with low-cost additive manufacturing. However, to fully realize their potential in sensing applications, high-performance analog amplifiers based on solution-processed semiconductors must be realized at scaled device dimensions.

One of the objectives of this invention is to disclose ohmic-contact-gated transistors based on solution-processed semiconducting single-walled carbon nanotubes to address this unmet need. This device design enables output current saturation in the short-channel limit without compromising output current drive. The resulting ohmic-contact-gated transistors are used in common-source amplifiers to attain the highest width-normalized output current (˜30 μA·μm⁻¹) and length-scaled signal gain (˜230 μm⁻¹) to date for solution-processed semiconductors. The utility of these amplifiers for emerging sensing technologies is demonstrated by the amplification of complex millivolt-scale analog biological signals including the outputs of electromyography, photoplethysmogram, and accelerometer sensors. Since the ohmic-contact-gated transistor design is compatible with other semiconducting materials, this work establishes a general route to high-performance, solution-processed analog electronics.

In one aspect of this invention, the ohmic-contact-gated transistor (OCGT) comprises a bottom gate electrode formed on a substrate; a first dielectric layer formed on the bottom gate electrode; a thin film formed of a semiconducting material on the first dielectric layer; a bottom contact formed on a part of the thin film; a second dielectric layer conformally grown on the bottom contact to result in a self-aligned dielectric extension from the bottom contact on the thin film; and a top contact formed on the second dielectric layer on the top of the bottom contact and fully overlapping with the dielectric extension to define a device channel in the thin film under the dielectric extension between the bottom contact and the top contact.

In one embodiment, the substrate comprises an undoped Si wafer.

In one embodiment, the semiconducting material comprises a solution-processed semiconducting material.

In one embodiment, the semiconducting material comprises solution-processed semiconducting single-walled carbon nanotubes (SWCNTs).

In one embodiment, the thin film comprises an SWCNT random network with about 99.9% semiconducting purity.

In one embodiment, the thin film comprises an SWCNT random network with a linear density of about 40 CNTs·μm⁻¹.

In one embodiment, the semiconducting material comprises MoS₂, MoSe₂, WS₂, WSe₂, InSe, GaTe, black phosphorus (BP), or related solution-processed semiconducting materials.

In one embodiment, the bottom gate electrode, the bottom contact and the top contact are formed of the same conductive material or different conductive materials including organic semiconductor and inorganic metal-oxides.

In one embodiment, each of the bottom gate electrode, the bottom contact and the top contact is formed of palladium (Pd), gold (Au), aluminum (Al), titanium (Ti), nickel (Ni), chromium (Cr), or other conductive materials including transparent indium tin oxides.

In one embodiment, the first dielectric layer and the second dielectric layer comprise a same dielectric material or different dielectric materials.

In one embodiment, each of the first dielectric layer and the second dielectric layer is formed of HfO₂, Al₂O₃, ZrO₂, ZnO, SiO₂, or dielectrics including alumina, hafnia, or zirconia and organic dielectric films grown by conformal molecular layer deposition.

In one embodiment, the second dielectric layer is a thin high-k dielectric layer formed of HfO₂ with a thickness of about 12 nm, k being a dielectric constant, and each of the bottom contact and the top contact is formed of an ohmic contact metal including Pd, for optimal short-channel performance of the SWCNT channel.

In one embodiment, an overlap region of the dielectric extension with the top contact determines a channel length (L) and creates a secondary gate that is shorted to the top contact.

In one embodiment, the OCGT geometry utilizes ohmic contacts with a short-channel length to achieve contact-gating with superior device performance.

In one embodiment, the OCGTs intrinsically mitigate short-channel (i.e., L<300 nm) effects by demonstrating an OCGT-based common-source amplifier.

In one embodiment, the OCGT-based common-source amplifier attains the highest width-normalized output current and length-scaled signal gain to date for solution-processed semiconductors.

In one embodiment, a signal gain of the OCGT-based common-source amplifier is quantified by applying a small input signal at the gate input that produces an inverted output signal.

In one embodiment, the OCGT is used in a common-source amplifier to attain the highest width-normalized output current and length-scaled signal gain to date for solution-processed semiconductors.

In one embodiment, the OCGT is characterized with exceptionally low width-normalized output conductance while maintaining high width-normalized output current levels.

In one embodiment, the use of ultrahigh purity semiconducting SWCNTs and ultrathin high-k dielectric layers provides improved electrostatic control of the channel, resulting in unipolar p-type transport with a simultaneously high Iₒₙ/I_{off} ratio, high output current, and negligible leakage current despite the short length of the channel.

In one embodiment, the SWCNT OCGTs achieves output current saturation concurrently with high output currents despite the short channel length.

In one embodiment, the design of the OCGT enables unprecedented levels of output current saturation in the short-channel limit for solution-processed semiconductors without compromising output current drive.

The OCGT geometry according to embodiments of the invention provides a key advantage by enhancing the gating of the semiconducting channel with both the bottom gate and top contact electrode without the need for additional terminals beyond the conventional gate-source-drain configuration. While contact-gating has been attempted in other device geometries, such as source-gated transistors, these devices rely on Schottky barrier contacts in 2D materials and/or vertical depletion regions in thicker semiconductors (organic or inorganic) that are not compatible with short-channel scaling. In contrast, the OCGT geometry utilizes ohmic contacts with a short-channel length to achieve contact-gating with superior device performance, while carbon nanotubes are compatible with sub-5-nm channel length. The OCGTs based on carbon nanotubes also provide a number of key advantages when compared with conventional source-gating schemes. In particular, the use of a dielectric extension to define channel length allows for the high-throughput fabrication of short-channel devices without requiring a high-end fabrication facility. Importantly, this robust fabrication design can be generalized to arbitrary semiconductors, including other atomically thin nanomaterials, by appropriately choosing metal electrodes for ohmic contacts.

The OCGT design enables transistors with short-channel current saturation at high output currents for solution-processed SWCNTs with ultrahigh semiconducting purity (>99.9%). Thus, OCGTs are not constrained by existing transistor tradeoffs between current saturation and output current that can limit analog applications. Among all previously reported amplifiers based on solution-processed semiconductors, common-source amplifiers using SWCNT OCGTs achieve the highest reported length-scaled signal gain (˜230 μm⁻¹) and the highest reported width-normalized output current (˜30 μA·μm⁻¹) to date. Furthermore, the utility of these amplifiers in practical sensing and health monitoring technologies is demonstrated by using them to amplify complex small analog signals commonly recorded in Internet of Things (IoT), and medical and consumer wearable devices. In particular, these analog amplifiers are used to amplify the complex millivolt-scale analog biological signals from the output of electromyography, photoplethysmogram, and accelerometer sensors. In this manner, the SWCNT OCGTs in this work can be used to create analog devices that can be readily integrated in emerging flexible and wearable electronics. Since the demonstrated OCGT fabrication design is compatible with other semiconducting materials, this invention can be employed as a general pathway for high-performance solution-processed analog electronics.

Another aspect of the invention relates to a circuit comprising at least one OCGT as disclosed above.

Yet another aspect of the invention relates to a device comprising at least one OCGT as disclosed above.

A further aspect of the invention relates to a method for fabricating an OCGT. The method comprises forming a bottom gate electrode on a substrate; forming a first dielectric layer on the bottom gate electrode; forming a thin film a semiconducting material on the first dielectric layer; forming a bottom contact on a part of the thin film; conformally growing a second dielectric layer on the bottom contact to result in a self-aligned dielectric extension from the bottom contact on the thin film; and forming a top contact on the second dielectric layer on the top of the bottom contact and fully overlapping with the dielectric extension to define a device channel in the thin film under the dielectric extension between the bottom contact and the top contact.

In one embodiment, said forming the thin film is performed by chemical vapor deposition (CVD), mechanical exfoliation, metal-organic chemical vapor deposition (MOCVD), or atomic layer deposition (ALD).

In one embodiment, the semiconducting material comprises a solution-processed semiconducting material.

In one embodiment, the semiconducting material comprises solution-processed semiconducting single-walled carbon nanotubes (SWCNTs) with about 99.9% semiconducting purity.

In one embodiment, the semiconducting material comprises MoS₂, MoSe₂, WS₂, WSe₂, InSe, GaTe, black phosphorus (BP), or related solution-processed semiconducting materials including organic semiconductor and inorganic metal-oxides.

In one embodiment, said forming the first dielectric layer is performed by photolithography and directional metal evaporation.

In one embodiment, said growing the second dielectric layer is performed with an undercut profile of negative photoresist combined with directional metal evaporation and conformal ALD of a dielectric oxide resulting in the self-aligned dielectric extension.

In one embodiment, the top contact electrode is patterned using photolithography and directional metal evaporation such that it fully overlaps the dielectric extending from the bottom contact.

In one embodiment, the bottom gate electrode, the bottom contact and the top contact are formed of the same conductive material or different conductive materials.

In one embodiment, each of the bottom gate electrode, the bottom contact and the top contact is formed of Pd, Au, Al, Ti, Ni, Cr, or other conductive materials including transparent indium tin oxides.

In one embodiment, the first dielectric layer and the second dielectric layer comprise a same dielectric material or different dielectric materials.

In one embodiment, each of the first dielectric layer and the second dielectric layer is formed of HfO₂, Al₂O₃, ZrO₂, ZnO, SiO₂, or dielectrics including alumina, hafnia, or zirconia and organic dielectric films grown by conformal molecular layer deposition.

This invention is the first work implementing solution-processed ohmic-contact-gated carbon nanotube transistors for high-performance analog amplifiers, which provides a commercially feasible opportunity to replace conventional crystalline semiconductors in the emerging flexible and wearable electronics market.

The invention may have widespread applications in the fields including, but are not limited to, transistors, thin-film transistors, solution-processed electronics, analog amplifiers, wearable physiological monitors.

Among other things, the invention provides a number of advantages. Existing solutions for high gain amplification include source-gated transistors from metal-oxide transistors that rely on Schottky contacts, resulting in significantly compromised currents. However, the OCGTs are not limited by thermionic emission at the Schottky barrier, thus surpassing competing technologies in the current density needed to drive subsequent circuitry.

Another competing technology is organic thin-film transistors that show ambient stability and aging issues, whereas carbon nanotubes are stable for years in ambient for durable wearable sensors that monitor physiological signals. Existing technology also uses silicon-based complementary metal-oxide semiconductor (CMOS) amplifiers; however, these circuits are not mechanically flexible and require high-end fabrication facilities. In contrast, carbon nanotube OCGT-based amplifiers are compatible with flexible substrates, and self-aligned sub-micron channel lengths can be achieved via standard photolithography.

These and other aspects of the invention are further described below. Without intent to limit the scope of the invention, exemplary instruments, apparatus, methods, and their related results according to the embodiments of the invention are given below. Note that titles or subtitles may be used in the examples for convenience of a reader, which in no way should limit the scope of the invention. Moreover, certain theories are proposed and disclosed herein; however, in no way they, whether they are right or wrong, should limit the scope of the invention so long as the invention is practiced according to the invention without regard for any particular theory or scheme of action.

### Example

Solution-Processed Ohmic-Contact-Gated Carbon Nanotube Transistors for High-Performance Analog Amplifiers

The growing demand for ubiquitous data collection has driven the development of sensing technologies based on flexible electronics. As a result, solution-processed semiconductors have been widely employed due to their mechanical flexibility and compatibility with low-cost additive manufacturing. However, to fully realize their potential in sensing applications, high-performance analog amplifiers based on solution-processed semiconductors must be realized at scaled device dimensions.

In this exemplary study, ohmic-contact-gated transistors (OCGTs) based on solution-processed semiconducting single-walled carbon nanotubes (SWCNTs) are intruded to address this unmet need. This device design enables unprecedented levels of output current saturation in the short-channel limit (i.e., channel lengths <300 nm) for solution-processed semiconductors without compromising output current drive. The resulting ohmic-contact-gated transistors are used in common-source amplifiers to attain the highest width-normalized output current (˜30 μA·μm⁻¹) and length-scaled signal gain (˜230 μm⁻¹) to date for solution-processed semiconductors. The utility of these amplifiers for emerging sensing technologies is demonstrated by the amplification of complex millivolt-scale analog biological signals including the outputs of electromyography, photoplethysmogram, and accelerometer sensors. Since the ohmic-contact-gated transistor design is compatible with other semiconducting materials, this work establishes a general route to high-performance, solution-processed analog electronics.

As a proof-of-concept, solution-processed semiconducting single-walled carbon nanotube (SWCNT) random networks are used to implement OCGTs. The resulting SWCNT OCGTs possess exceptionally low width-normalized output conductance (˜60 nS·μm⁻¹) while maintaining high width-normalized output current levels (˜30 μA·μm⁻¹), thus overcoming the tradeoff that is typically observed in conventional short-channel field-effect transistors (FETs). These SWCNT OCGTs are then used in common-source amplifiers to attain the highest width-normalized output current (˜30 μA·μm⁻¹) and length-scaled signal gain (˜230 μm⁻¹) to date for solution-processed semiconductors. The utility and robustness of these analog amplifiers is demonstrated with a diverse set of analog signals from detectors commonly found in IoT and medical devices, including electromyography, photoplethysmogram, and accelerometer sensors. Because the OCGT design can be generalized to other semiconducting materials, this work has wide-ranging implications for solution-processed analog electronics.

### Fabrication of Ohmic-Contact-Gated Transistors

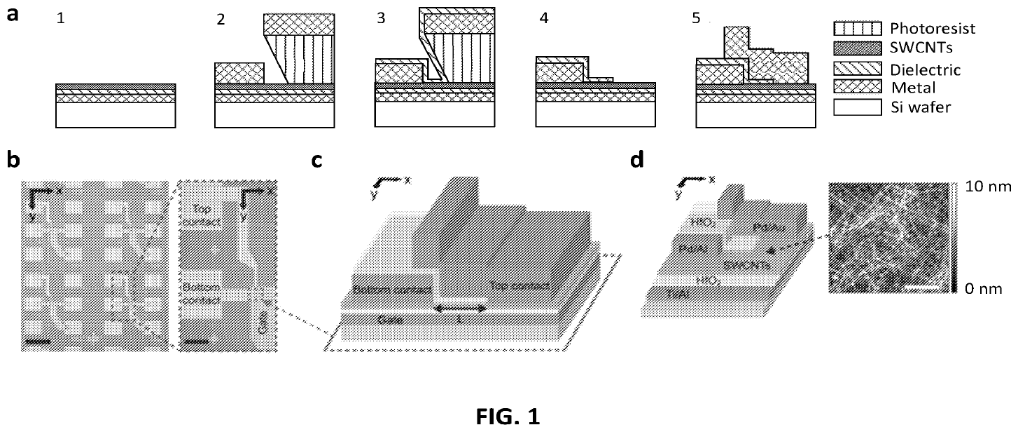

In one embodiment shown in FIG. 1, SWCNT OCGTs were fabricated on an undoped Si wafer with a 300 nm thick thermal oxide. The role of the thermal oxide is to enable optical contrast for atomically thin semiconductors. Negative photolithography, thermal evaporation (10 nm of Cr, then 50 nm of Au), and liftoff in acetone were used to define contact pads. Negative photolithography and e-beam evaporation (5 nm of Ti, then 15 nm of Al) were used to deposit patterned gate electrodes. Directly following e-beam evaporation, a conformal HfO₂ (12 nm) gate dielectric was grown via ALD using tetrakis(dimethylamido)hafnium(IV) (TDMAH) and water at 100° C. (Savannah S100, Cambridge NanoTech). Liftoff was then performed in Remover PG (MicroChem) heated to 80° C. The substrates were treated with reactive ion etching (RIE) in an O₂ plasma atmosphere (100 W, 4 Pa, 2 min, 10 sccm of O₂), a 5 min dip in poly-L-lysine solution (0.1% w/v in water, Sigma-Aldrich P8920), and a gentle rinse in DI water. Ultrahigh purity (99.9% semiconducting purity) SWCNTs were deposited on this modified surface by dipping the substrates in IsoSol-S100 (NanoIntegris) solution, followed by a gentle rinse with 5 mL of toluene to remove excess material. The substrates were then annealed at 200° C. in ambient, followed by cleaning with acetone and IPA. Positive photolithography, RIE in an O₂ plasma atmosphere (100 W, 26.5 Pa, 15 sec, 20 sccm of 02), and liftoff in acetone were used to define the SWCNT channel. Negative photolithography, e-beam evaporation (40 nm of Pd, then 10 nm of Al), HfO₂ (12 nm) deposition via ALD and liftoff in heated Remover PG (MicroChem, Inc.) were again used to define the patterned bottom contact electrodes with a dielectric extension due to the photoresist undercut. The length of this dielectric extension was controlled by changing the development time of the negative photoresist, and its length was characterized using AFM. Negative photolithography, e-beam evaporation (70 nm of Pd, then 5 nm of Au) and liftoff in acetone were used to define the patterned top contact electrode such that it overlapped the dielectric extension of the bottom contact electrode.

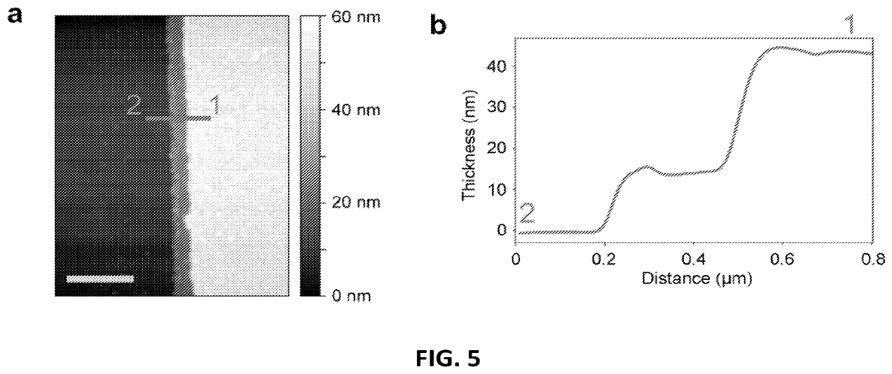

Specifically referring to FIG. 1, OCGTs are fabricated using a self-aligned method compatible with conventional photolithography (panel a of FIG. 1). First, a bottom gate electrode and gate oxide layer are defined on an undoped Si wafer, followed by the deposition of solution-processed SWCNTs with 99.9% semiconducting purity (panel a of FIG. 1, step 1). Another step of photolithography and directional metal evaporation are then used to define the bottom contact electrode (panel a of FIG. 1, step 2). A conformal dielectric is grown using atomic layer deposition (ALD) prior to liftoff (panel a of FIG. 1, step 3), resulting in a self-aligned dielectric extending from the bottom contact due to the undercut of the negative photoresist (panel a of FIG. 1, step 4; FIG. 5). Lastly, the top contact electrode is patterned using photolithography and directional metal evaporation such that it fully overlaps the dielectric extending from the bottom contact (panel a of FIG. 1, step 5). The optical micrograph in panel b of FIG. 1 shows the lateral layout of a fully fabricated OCGT. The intentional overlap of the dielectric extension with the top electrode determines the device channel length (L) and creates a secondary gate that is shorted to the top electrode. A 3D schematic of the OCGT device design in panel c of FIG. 1 highlights how L is defined by the contact electrodes and the dielectric extension. The device layout and dielectric extension are designed such that the OCGT has a channel width (W) of 10 μm and L of 280 nm. In addition, a thin high-k dielectric (12 nm HfO₂) and an ohmic contact metal (Pd) are used for optimal short-channel performance of the SWCNT channel. Where appropriate, Al is used in the electrode metal stack to seed subsequent ALD dielectric growth. Artificial shifting of the layers of a SWCNT OCGT along the y-direction to reveal the underlying structure and materials is shown in panel d of FIG. 1, along with an atomic force microscopy (AFM) image of the SWCNT random network with a linear density of ˜40 CNTs·μm⁻¹.

The OCGT geometry provides a key advantage by enhancing the gating of the semiconducting channel with both the bottom gate and top contact electrode without the need of additional terminals beyond the conventional gate-source-drain configuration. While contact-gating has been attempted in other device geometries, such as source-gated transistors, these devices rely on Schottky barrier contacts in 2D materials and/or vertical depletion regions in thicker semiconductors (organic or inorganic) that are not compatible with short-channel scaling. In contrast, the OCGT geometry utilizes ohmic contacts with a short-channel length to achieve contact-gating with superior device performance. The OCGT fabrication process also provides a number of key advantages when compared with conventional source-gating schemes. In particular, the use of a dielectric extension to define L allows for the high-throughput fabrication of short-channel devices using coarser resolution patterning schemes. Importantly, this robust fabrication design can be generalized to arbitrary semiconductors including other atomically thin nanomaterials and van der Waals heterojunctions.

### Performance Metrics of SWCNT OCGTs

The output, transfer, and leakage characteristics of the fabricated OCGTs were measured using a Cascade Microtech Summit 12000 semi-automatic ambient probe station with a Keithley 4200-SCS system. Data were collected using a custom Keithley 4200 test module. Data analysis was performed using custom MATLAB and python scripts.

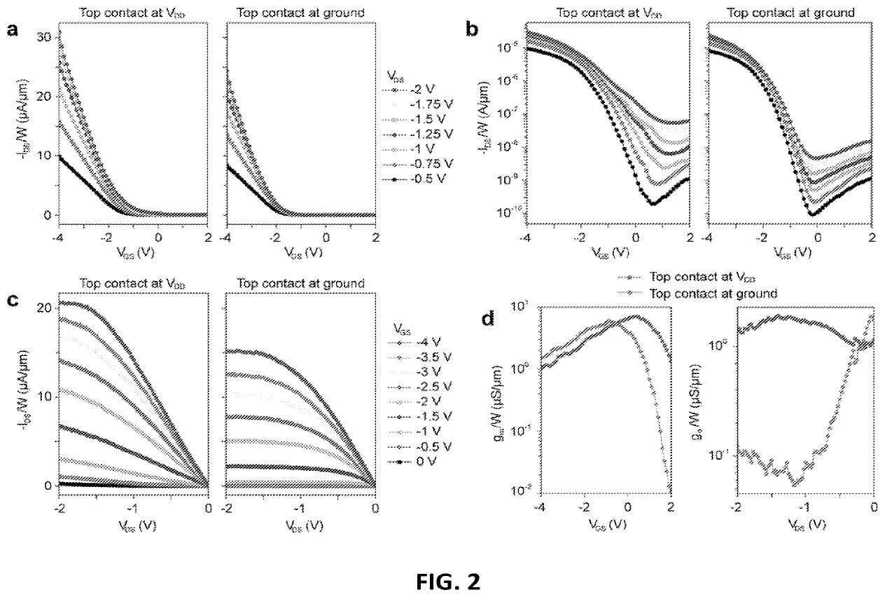

The electronic transport of SWCNT OCGTs was measured in ambient conditions under two distinct modes of operation. In one mode, the bottom contact is held at the supply voltage (V_{DD}) while the top contact, which overlaps the semiconducting channel and bottom contact, is grounded. Conversely, in the second mode of operation, the bottom contact is grounded while the overlapping top contact is at V_{DD}. Unlike conventional FETs, this switch in drain-source biasing polarity leads to significant changes in the output and transfer characteristics of OCGTs. This polarity dependence is due to the intrinsic electrostatic asymmetry arising from the geometry of the contacts of OCGTs, where the field effect in the channel is controlled by both the bottom gate and the overlapping top contact. The transfer and output characteristics under these two modes of operation were collected for 67 OCGTs. The behavior of a representative OCGT is discussed below and shown in FIG. 2 for clarity.

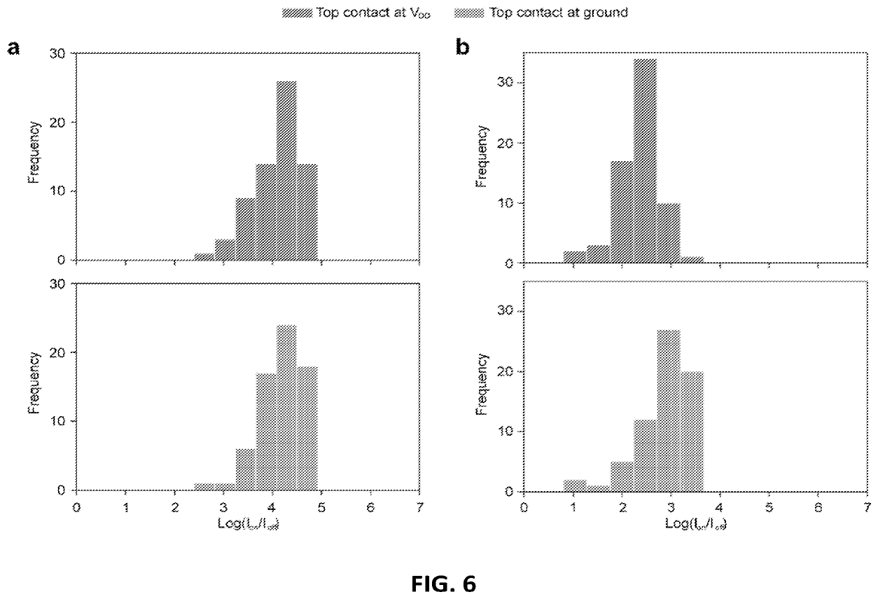

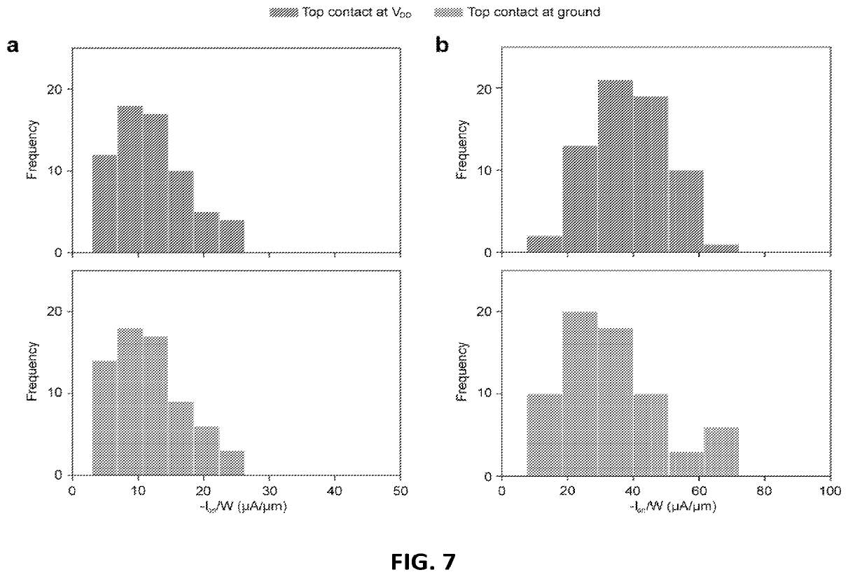

The transfer characteristics (I_{DS}−V_{GS}) of the SWCNT OCGTs are measured by sweeping the gate-source voltage (V_{GS}) at different values of the drain-source voltage (V_{DS}). The linear and log-linear transfer characteristics of a typical device are shown in panels a-b of FIG. 2, respectively, for both modes of operation described above (i.e., top contact at ground and top contact at V_{DD}). The use of ultrahigh purity semiconducting SWCNTs and ultrathin high-k (k being dielectric constant) dielectric layers provides improved electrostatic control of the channel, resulting in unipolar p-type transport with a simultaneously high Iₒₙ/I_{off} ratio (>10⁴), high output current (˜10 μA·μm⁻¹), and negligible leakage current (˜10 pA·μm⁻¹), despite the short length of the channel (L<300 nm). While the Iₒₙ/I_{off} ratio decreases with increasing output current (i.e., increasing |V_{DS}|) in conventional FETs, this deleterious effect is mitigated in OCGTs when the top contact is grounded. At low values of |V_{DS}| (−0.5 V), the difference between the modes of operation for both log(Iₒₙ/I_{off}) and |Iₒₙ|/W is minimal (i.e., the median log(Iₒₙ/I_{off}) is 4.5 and 4.4 and the median |Iₒₙ|/W is 13 and 14 μA·μm⁻¹ for the top contact at ground and the top contact at V_{DD}, respectively). However, at a high |V_{DS}| (−2 V), the Iₒₙ/I_{off} ratio is significantly improved when the top contact is grounded with only a small loss in |Iₒₙ|/W (i.e., the median log (Iₒₙ/I_{off}) is 3.1 and 2.6 and the median |Iₒₙ|/W is 39 and 44 μA·μm⁻¹ for the top contact at ground and the top contact at V_{DD}, respectively; FIGS. 6 and 7). This improvement in Iₒₙ/I_{off} ratio increases with increasing |V_{DS}|, providing a key advantage over conventional FET designs.

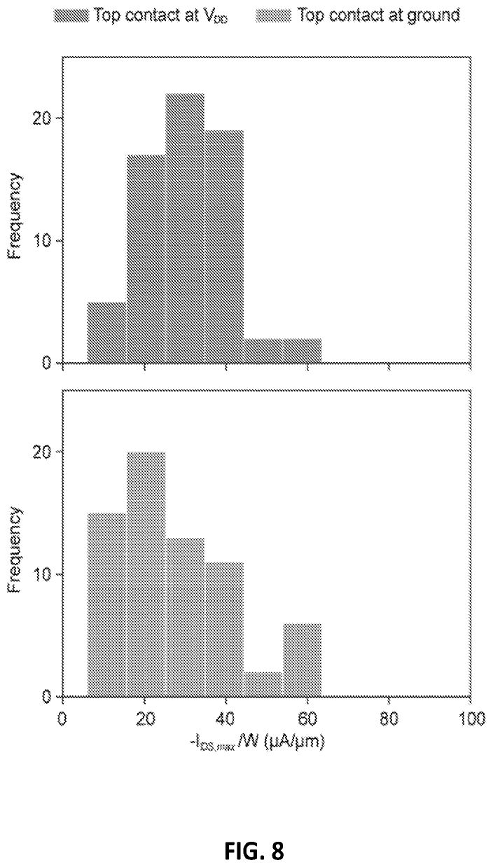

The output characteristics (I_{DS}−V_{DS}) of the SWCNT OCGTs were measured by sweeping VAS for different values of V_{GS}. The linear output characteristics of a representative OCGT in both modes of operation are shown in panel c of FIG. 2. The use of ohmic contacts (i.e., Pd) and high-density SWCNT channels results in high output currents, such that at a high |V_{GS}| (−4 V), the OCGTs exhibit a median maximum output current (|I_{DS,max}|/W) of 29 and 33 μA·μm⁻¹ for the top contact at ground and the top contact at V_{DD}, respectively, as shown in FIG. 8. Most notably, at high |V_{GS}| biases with the top contact at ground, SWCNT OCGTs achieve output current saturation concurrently with high output currents despite the short channel length. This observation is in sharp contrast with previously published short-channel SWCNT FETs, where output current saturation is either limited to overall low currents or the current saturation regime is not realized at all. Additionally, output current saturation is achieved despite the use of SWCNT high-density random networks (as opposed to aligned SWCNT arrays) that are susceptible to deleterious electrostatic screening of the applied gate field. These results highlight how the OCGT contact geometry intrinsically enhances electrostatic gating, thereby reducing short-channel effects (e.g., channel-length modulation) and relaxing the demands on SWCNT assembly (e.g., eliminating the need for SWCNT alignment schemes).

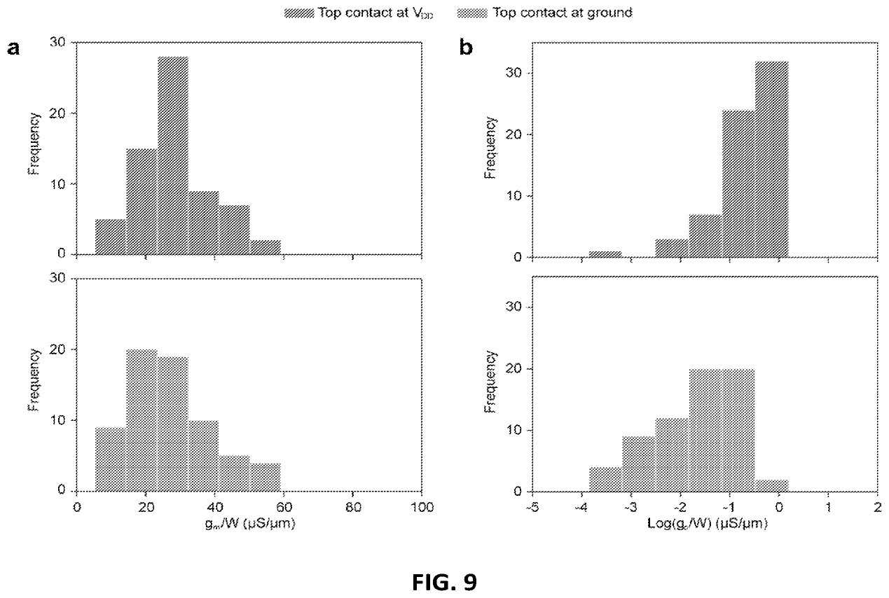

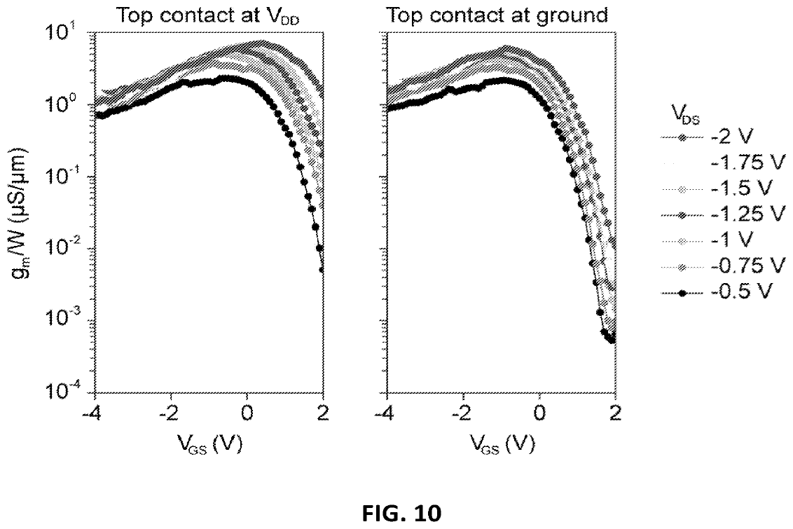

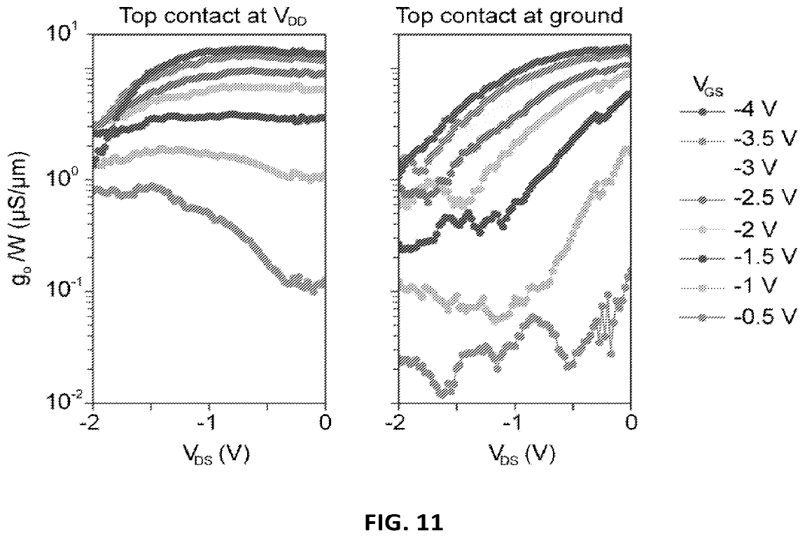

These advantages are manifested in two key transistor metrics: transconductance (i.e., gₘ, where gₘ=dI_{DS}/dV_{GS} at a fixed V_{DS}) and output conductance (i.e., gₒ, where gₒ=rₒ⁻¹=dI_{DS}/dV_{DS} at a fixed V_{GS}, where rₒ is the output resistance). Panel d of FIG. 2 shows the log-linear behavior of width-normalized gₘ as a function of V_{GS} at V_{DS}=−2 V and width-normalized gₒ as a function of V_{DS} at V_{GS}=−1 V for a representative device in both modes of operation. The maximum gₘ is similar for both modes of operation (i.e., the median maximum gₘ/W is 31 μS·μm⁻¹ for both the top contact at ground and the top contact at V_{DD}; panel a of FIG. 9). However, gₒ is significantly improved due to saturation of the output current such that, at high output currents (i.e., high |V_{DS}|), gₒ is decreased by an order of magnitude when the top contact is at ground (i.e., the median gₒ/W is 60 and 670 nS·μm⁻¹ for the top contact at ground and the top contact at V_{DD}, respectively; panel b of FIG. 9). This improvement in gₒ with minimal compromise of gₘ (FIGS. 10 and 11) highlights the potential for using OCGTs in highly scaled flexible analog circuit applications. Table 1 provides a summary of the aforementioned SWCNT OCGT performance metrics.

TABLE 1
Median values of key performance metrics for 67 SWCNT OCGTs

| | | | Top contact bias | |
|---|---|---|---|---|
| | Metric | Bias | V_{DD} | Ground |
| Transfer | Log(Iₒₙ/I_{off}) | V_{DS} = −0.5 V | 4.4 | 4.5 |
| characteristic | | V_{DS} = −2 V | 2.6 | 3.1 |
| | Iₒₙ/W | V_{DS} = −0.5 V | −14 μA · μm⁻¹ | −13 μA · μm⁻¹ |
| | | V_{DS} = −2 V | −44 μA · μm⁻¹ | −39 μA · μm⁻¹ |
| | gₘ/W | V_{DS} = −2 V | 31 μS · μm⁻¹ | 31 μS · μm⁻¹ |
| Output | I_{DS, max}/W | V_{GS} = −4 V | −33 μA · μm⁻¹ | −29 μA · μm⁻¹ |
| characteristic | gₒ/W | V_{GS} = −1 V | 670 nS · μm⁻¹ | 60 nS · μm⁻¹ |

It should be emphasized that the present OCGTs operate in a distinct fashion in comparison to previously reported source-gated transistors based on semiconductor thin films. Conventional source-gated transistors rely on the creation of an extended depletion region under the contacts that blocks carrier injection at higher biases, resulting in superior current saturation at smaller biases but at the expense of overall current density. Thus, conventional source-gating concepts rely on the finite thickness of the semiconductors. Similarly, a recent demonstration of source-gating using overlapping electrodes in monolayer semiconductor (MoS₂) transistors involved Schottky contacts which limited output current density. Because the OCGTs presented here rely exclusively on electrostatic control of the channel, the resulting devices avoid tradeoffs between current saturation and on-state current density, thereby enabling simultaneous improvements in traditionally competing device metrics.

### High Gain Amplification for Practical Sensing Systems

Amplifier measurements were performed using the Cascade Microtech Summit 12000 semi-automatic ambient probe station, a Keithley 2400 unit (current source and voltage supply), an Agilent 33500B waveform generator (input voltage signal), and a Tektronix TBS 2104 digital oscilloscope (input/output voltage measurement). The Keithley 2400 unit was operated as a current source at an output current of −30 μA with a maximum V_{DD} of −2.5 V. All circuit components were connected using a custom breadboard. Sinusoidal input signals were generated using the native software of the waveform generator. Custom signals (i.e., electromyography, photoplethysmogram, and accelerometer) were imported and generated using the arbitrary signal function of the waveform generator. Accelerator input signal data were collected from the x-axis output of a SparkFun Triple Axis Accelerometer (ADXL335) attached to a waving hand. Electromyography and photoplethysmogram input signal data were collected from online databases. Output voltage signal data were collected using a digital oscilloscope, and the data were then analyzed using custom python scripts.

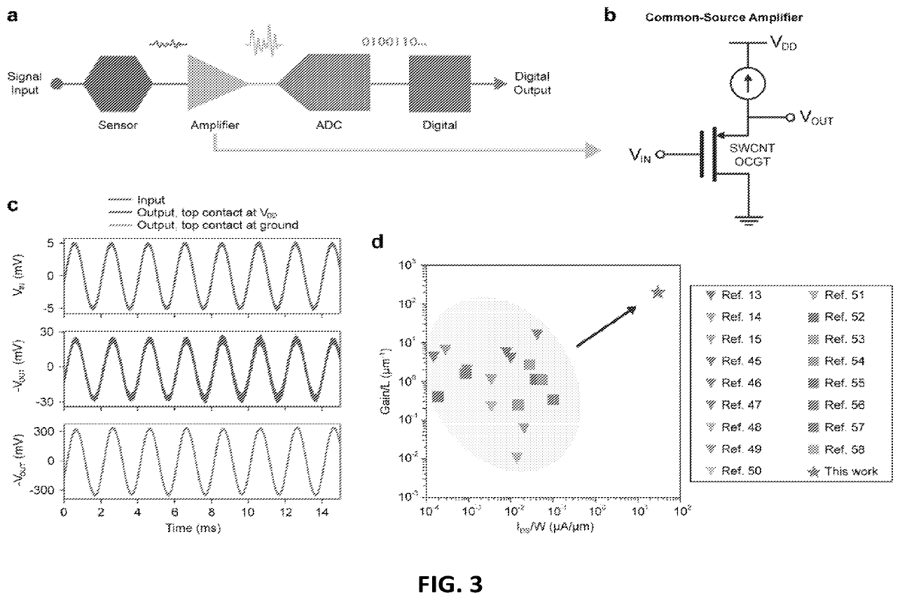

The enhanced electrostatic control in SWCNT OCGTs results in significant improvements in transistor metrics, namely, gₘ and gₒ, which are key parameters in small-signal amplifiers for analog acquisition systems. A typical signal acquisition process is illustrated in panel a of FIG. 3, where the small analog signal is amplified, converted to a digital signal, and then processed into a digital output. Small-signal amplifiers play a critical role in the acquisition of low-amplitude sensory data since they drive the subsequent ADC components and increase the signal amplitude to appropriate levels for analog signal digitization. Therefore, practical sensing systems require small-signal amplifiers with both high signal gain and high current output.

Solution-processed semiconductors have been employed in emerging sensing systems due to their potential for low-cost, flexible electronics. However, amplifiers based on these materials suffer from low output currents and transistor scaling limitations. As a result, an unmet need in these emerging sensing systems are amplifiers based on solution-processed semiconductors that achieve high output current (i.e., |I_{DS}|/W) and high signal gain at scaled dimensions (i.e., gain/L). The performance of OCGTs for these key metrics is characterized by using them in single-stage, single-transistor common-source amplifiers (panel b of FIG. 3). Common-source amplifiers have a small voltage signal at the transistor gate (V_{IN}) that is amplified (V_{OUT}) with a gain of V_{OUT}/V_{IN}˜−gₘ/gₒ. Common-source amplifiers are ideal for the small input signals in solution-processed sensing systems due to their high input impedance resulting from dielectrics with negligible leakage. The signal gain of OCGT-based common-source amplifiers is quantified by applying a small sinusoidal input signal V_{IN} at the gate input that produces an inverted output signal V_{OUT}. The amplified output V_{OUT} was characterized for both modes of operation of the OCGT, where a substantial improvement in gain was expected when the top contact is grounded due to ten-fold lower gₒ compared to when the top contact is at V_{DD}. As shown in panel c of FIG. 3, a sinusoidal V_{IN} with an amplitude of 5 mV is amplified with a gain of ˜5 and ˜68 when the top contact is at V_{DD} and the top contact is at ground, respectively. This increase in signal gain highlights the advantages of the OCGT geometry, where a high signal gain and high output current can be achieved at short-channel lengths. To further illustrate this point, panel d of FIG. 3 shows a comparison plot of width-normalized current (|I_{DS}|/W) and length-scaled signal gain (gain/L) values for the best solution-processed amplifiers in previously reported literature. Evidently, the present OCGT-based amplifiers (panel d of FIG. 3, red star) outperform the best amplifier by over one and two orders of magnitude in length-scaled signal gain and width-normalized current, respectively.

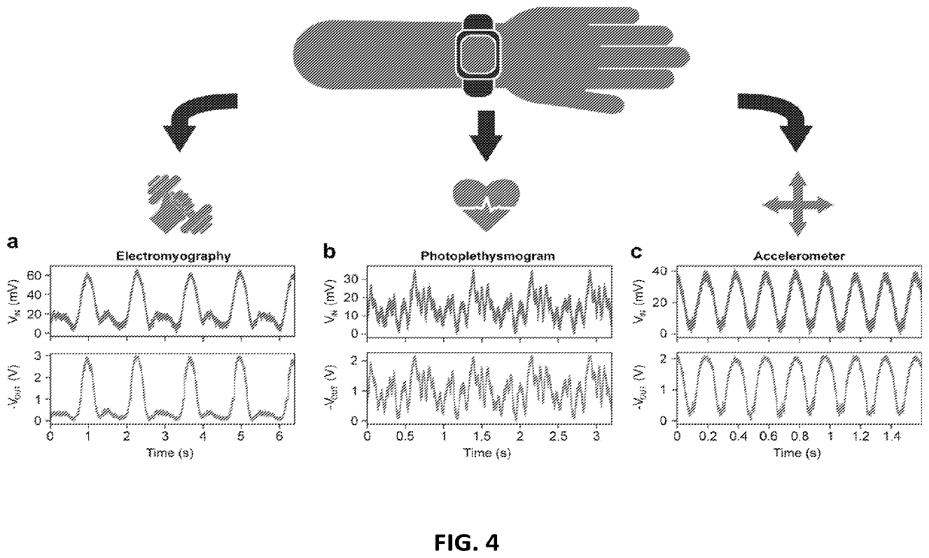

To further demonstrate the utility of OCGT-based amplifiers in sensing systems, the signal gain from complex analog signals was characterized. In particular, three raw sensor signals from common consumer and medical-grade wearable devices were used. The first signal is an enveloped electromyography (EMG) signal, which measures electrical activity at the surface of a muscle and is commonly used in the assessment of muscle and motor neuron health (panel a of FIG. 4). The second signal is a photoplethysmogram (PPG) signal, which measures blood volume changes and is commonly used in heart rate monitoring (panel b of FIG. 4). The third signal is an accelerometer signal, which is commonly used for monitoring physical activity (panel c of FIG. 4). Beyond their distinct shapes, these signals range in amplitude from 10-60 mV and frequency from 0.5-5 Hz. As shown in FIG. 4, the signal gains from these biologically relevant signals range from 50-60. The magnitude of signal gain in these measurements agrees with the common-source amplifier characterization detailed in FIG. 3, and demonstrates the potential for SWCNT OCGT-based amplifiers in emerging sensing technologies. Furthermore, the fabrication design of OCGT devices can be applied to other semiconducting materials, providing a general pathway to high-performance analog electronics based on solution-processed semiconductors.

### CONCLUSION

The exemplary example has demonstrated a novel OCGT design that enables transistors with short-channel current saturation at high output currents for solution-processed SWCNTs with ultrahigh semiconducting purity. Since the existing transistor tradeoffs between current saturation and output current can limit analog applications, the example showed OCGTs intrinsically mitigate short-channel (i.e., L<300 nm) effects by demonstrating an OCGT-based common-source amplifier. Among all previously reported amplifiers based on solution-processed semiconductors, common-source amplifiers using SWCNT OCGTs achieve the highest reported length-scaled signal gain (˜230 μm⁻¹) and the highest reported width-normalized output current (˜30 μA·μm⁻¹) to date. Furthermore, the example demonstrated the utility of these amplifiers in practical sensing and health monitoring technologies by using them to amplify complex small analog signals commonly recorded in medical and consumer wearable devices. In this manner, the SWCNT OCGTs disclosed in the application can be used to create analog devices that can be readily integrated in emerging flexible and wearable electronics. Since the demonstrated OCGT fabrication design is compatible with other semiconducting materials, this work can be employed as a general pathway for high-performance solution-processed analog electronics.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the invention pertains without departing from its spirit and scope. Accordingly, the scope of the invention is defined by the appended claims rather than the foregoing description and the exemplary embodiments described therein.

Some references, which may include patents, patent applications, and various publications, are cited and discussed in the description of this invention. The citation and/or discussion of such references is provided merely to clarify the description of the invention and is not an admission that any such reference is “prior art” to the invention described herein. All references cited and discussed in this specification are incorporated herein by reference in their entireties and to the same extent as if each reference was individually incorporated by reference.

### LIST OF REFERENCES

[1]. Chiang, M. & Zhang, T. Fog and IoT: An overview of research opportunities. IEEE Internet Things J3, 854-864 (2016).
[2]. LeCun, Y., Bengio, Y. & Hinton, G. Deep learning. Nature 521, 436-444 (2015).
[3]. Shi, W. & Dustdar, S. The promise of edge computing. Computer 49, 78-81 (2016).
[4]. Li, H., Ota, K. & Dong, M. Learning IoT in edge: Deep learning for the Internet of Things with edge computing. IEEE Network 32, 96-101 (2018).
[5]. Zheng, Y. et al. Unobtrusive sensing and wearable devices for health informatics. IEEE Trans. Biomed. Eng. 61, 1538-1554 (2014).
[6]. Kim, D.-H., Ghaffari, R., Lu, N. & Rogers, J. A. Flexible and stretchable electronics for biointegrated devices. Annu. Rev. Biomed. Eng. 14, 113-128 (2012).
[7]. Bandodkar, A. J. & Wang, J. Non-invasive wearable electrochemical sensors: a review. Trends Biotechnol. 32, 363-371 (2014).
[8]. Gupta, S., Navaraj, W. T., Lorenzelli, L. & Dahiya, R. Ultra-thin chips for high-performance flexible electronics. npj Flex. Electron. 2, 8 (2018).
[9]. Chen, K. et al. Printed carbon nanotube electronics and sensor systems. Adv. Mater. 28, 4397-4414 (2016).
[10]. Eslamian, M. Inorganic and organic solution-processed thin film devices. Nano-Micro Lett. 9, 3 (2016).
[11]. Abbel, R., Galagan, Y. & Groen, P. Roll-to-roll fabrication of solution processed electronics. Adv. Eng. Mater. 20, 1701190 (2018).
[12]. Xiang, L., Zhang, H., Hu, Y. & Peng, L.-M. Carbon nanotube-based flexible electronics. J. Mater. Chem. C 6, 7714-7727 (2018).
[13]. Sugiyama, M. et al. An ultraflexible organic differential amplifier for recording electrocardiograms. Nat. Electron. 2, 351-360 (2019).
[14]. Matsui, H. et al. Printed 5-V organic operational amplifiers for various signal processing. Sci. Rep. 8, 8980 (2018).
[15]. Jiang, C. et al. Printed subthreshold organic transistors operating at high gain and ultralow power. Science 363, 719-723 (2019).
[16]. Torricelli, F., Colalongo, L., Raiteri, D., Kovacs-Vajna, Z. M. & Cantatore, E. Ultra-high gain diffusion-driven organic transistor. Nat. Commun. 7, 10550 (2016).
[17]. Zhang, Z. et al. Doping-free fabrication of carbon nanotube based ballistic CMOS devices and circuits. Nano Lett. 7, 3603-3607 (2007).
[18]. Lau, C., Srimani, T., Bishop, M. D., Hills, G. & Shulaker, M. M. Tunable n-type doping of carbon nanotubes through engineered atomic layer deposition HfOₓ films. ACS Nano 12, 10924-10931 (2018).
[19]. Zhong, D. et al. Gigahertz integrated circuits based on carbon nanotube films. Nat. Electron. 1, 40-45 (2018).
[20]. Gaviria Rojas, W. A. & Hersam, M. C. Chirality-enriched carbon nanotubes for next-generation computing. Adv. Mater., DOI: 10.1002/adma.201905654 (2020).
[21]. Shannon, J. M. & Gerstner, E. G. Source-gated thin-film transistors. IEEE Electron Device Lett. 24, 405-407 (2003).
[22]. Sporea, R. A. et al. Performance trade-offs in polysilicon source-gated transistors. Solid-State Electron. 65-66, 246-249 (2011).
[23]. Beck, M. E. & Hersam, M. C. Emerging opportunities for electrostatic control in atomically thin devices. ACS Nano 14, 6498-6518 (2020).
[24]. Sangwan, V. K. et al. Self-aligned van der Waals heterojunction diodes and transistors. Nano Lett. 18, 1421-1427 (2018).
[25]. Shannon, J. M. & Gerstner, E. G. Source-gated transistors in hydrogenated amorphous silicon. Solid-State Electron. 48, 1155-1161 (2004).
[26]. Sporea, R. A., Trainor, M. J., Young, N. D., Shannon, J. M. & Silva, S. R. P. Source-gated transistors for order-of-magnitude performance improvements in thin-film digital circuits. Sci. Rep. 4, 4295 (2014).
[27]. Zhang, J. et al. Extremely high-gain source-gated transistors. Proc. Natl. Acad. Sci. U.S.A. 116, 4843-4848 (2019).
[28]. Lee, D. et al. Three-dimensional fin-structured semiconducting carbon nanotube network transistor. ACS Nano 10, 10894-10900 (2016).
[29]. Zhao, C. et al. Exploring the performance limit of carbon nanotube network film field-effect transistors for digital integrated circuit applications. Adv. Funct. Mater. 29, 1808574 (2019).
[30]. Han, S.-J. et al. High-speed logic integrated circuits with solution-processed self-assembled carbon nanotubes. Nat. Nanotechnol. 12, 861-865 (2017).
[31]. Brady, G. J. et al. Quasi-ballistic carbon nanotube array transistors with current density exceeding Si and GaAs. Sci. Adv. 2, e1601240 (2016).
[32]. Jang, S., Kim, B., Geier, M. L., Hersam, M. C. & Dodabalapur, A. Short channel field-effect-transistors with inkjet-printed semiconducting carbon nanotubes. Small 11, 5505 5509 (2015).
[33]. Cao, Q. et al. Gate capacitance coupling of singled-walled carbon nanotube thin-film transistors. Appl. Phys. Lett. 90, 023516 (2007).
[34]. Veeraraghavan, S. & Fossum, J. G. Short-channel effects in SOI MOSFETs. IEEE Trans. Electron Devices 36, 522-528 (1989).
[35]. Cunha, A. I. A., Schneider, M. C. & Galup-Montoro, C. An MOS transistor model for analog circuit design. IEEE J. Solid-State Circuits 33, 1510-1519 (1998).
[36]. Sambandan, S. High-gain amplifiers with amorphous-silicon thin-film transistors. IEEE Electron Device Lett. 29, 882-884 (2008).
[37]. Hosticka, B. J. CMOS sensor systems in Proceedings of International Solid State Sensors and Actuators Conference (Transducers '97). (IEEE, 1997).
[38]. Avilez Sanches, O. F. EMG dataset in Lower Limb Data Set (UCI Machine Learning Repository). https://archive.ics.uci.edu/ml/datasets/EMG+dataset+in+Lower+Limb (2014).
[39]. Dua, D. & Graff, C. UCI Machine Learning Repository. http://archive.ics.uci.edu/ml (2019).
[40]. Shiavi, R., Frigo, C. & Pedotti, A. Electromyographic signals during gait: Criteria for envelope filtering and number of strides. Med. Biol. Eng. Comput. 36, 171-178 (1998).
[41]. Jarchi, D. & Casson, J. A. Description of a database containing wrist PPG signals recorded during physical exercise with both accelerometer and gyroscope measures of motion. Data 2, DOI: 10.3390/data2010001 (2017).
[42]. Goldberger, A. L. et al. PhysioBank, PhysioToolkit, and PhysioNet: Components of a NewResearch resource for complex physiologic signals. Circulation 101, e215-e220 (2000).
[43]. Elgendi, M. On the analysis of fingertip photoplethysmogram signals. Curr. Cardiol. Rev. 8, 14-25 (2012).
[44]. Pantelopoulos, A. & Bourbakis, N. G. A survey on wearable sensor-based systems for health monitoring and prognosis. IEEE Trans. Syst., Man, Cybern. 40, 1-12 (2010).
[45]. Sekitani, T. et al. Ultraflexible organic amplifier with biocompatible gel electrodes. Nat. Commun. 7, 11425 (2016).
[46]. Nausieda, I. et al. Mixed-signal organic integrated circuits in a fully photolithographic dual threshold voltage technology. IEEE Trans. Electron Devices 58, 865-873 (2011).
[47]. Maiellaro, G. et al. High-gain operational transconductance amplifiers in a printed complementary organic TFT technology on flexible foil. IEEE Trans. Circuits Syst. I, Reg. Papers 60, 3117-3125 (2013).
[48]. Guerin, M. et al. High-gain fully printed organic complementary circuits on flexible plastic foils. IEEE Trans. Electron Devices 58, 3587-3593 (2011).
[49]. Marien, H., Steyaert, M., Veenendaal, E. v. & Heremans, P. DC-DC converter assisted two-stage amplifier in organic thin-film transistor technology on foil in 2011 Proceedings of the ESSCIRC (ESSCIRC). (IEEE, 2011).
[50]. Chang, J., Zhang, X., Ge, T. & Zhou, J. Fully printed electronics on flexible substrates: High gain amplifiers and DAC. Org. Electron. 15, 701-710 (2014).
[51]. Gay, N. et al. Analog signal processing with organic FETs in 2006 IEEE International Solid State Circuits Conference—Digest of Technical Papers. (IEEE, 2006).
[52]. Marten, H., Steyaert, M., Aerle, N. v. & Heremans, P. An analog organic first-order CT ΔΣ ADC on a flexible plastic substrate with 26.5 dB precision in 2010 IEEE International Solid-State Circuits Conference—(ISSCC). (IEEE, 2011).
[53]. Ishida, K. et al. A 100-V AC energy meter integrating 20-V organic CMOS digital and analog circuits with a floating gate for process variation compensation and a 100-V organic pMOS rectifier. IEEE J. Solid-State Circuits 47, 301-309 (2012).
[54]. Fuketa, H. et al. 1 μm-thickness ultra-flexible and high electrode-density surface electromyogram measurement sheet with 2 V organic transistors for prosthetic hand control. IEEE Trans. Biomed. Circuits Syst. 8, 824-833 (2014).
[55]. Kheradmand-Boroujeni, B. et al. A fully-printed self-biased polymeric audio amplifier for driving fully-printed piezoelectric loudspeakers. IEEE Trans. Circuits Syst. I, Reg. Papers 63, 785-794 (2016).
[56]. Torres-Miranda, M. et al. High-speed plastic integrated circuits: Process integration, design, and test. IEEE Trans. Emerg. Sel. Topics Circuits Syst. 7, 133-146 (2017).
[57]. Kim, D., Kim, Y., Choi, K., Lee, D. & Lee, H. A solution-processed operational amplifier using direct light-patterned a-InGaZnO TFTs. IEEE Trans. Electron Devices 65, 1796-1802 (2018).
[58]. Petti, L. et al. Gain-tunable complementary common-source amplifier based on a flexible hybrid thin-film transistor technology. IEEE Electron Device Lett. 38, 1536-1539 (2017).
[59]. Shannon, J. M. et al., Transistor Manufacture, US20080224184A1 (2008).
[60]. Shannon J. M. et al., Field effect transistor, U.S. Pat. No. 7,763,938B2 (2010).
[61]. Shannon J. M. et al., Phototransistor with source layer between barrier layer and photosensitive semiconductor layer and a gate layer for controlling the barrier height of the barrier layer, U.S. Pat. No. 7,723,667B2 (2010).
[62]. Ludwig, L. F., Nanoelectronic differential amplifiers and related circuits having carbon nanotubes, graphene nanoribbons, or other related materials, U.S. Pat. No. 7,838,809B2 (2010).
[63]. Ludwig, L. F., Hierarchically-modular nanoelectronic differential amplifiers, op amps, and associated current sources utilizing carbon nanotubes, graphene nanoribbons, printed electronics, polymer semiconductors, or other related materials, U.S. Pat. No. 8,522,184B2 (2013).
[64]. Shannon, J. M. et al., Source-gated transistors in hydrogenated amorphous silicon. Solid-State Electron. 48, 1155-1161 (2004)
[65]. Sporea, R. A. et al., Source-gated transistors for order-of-magnitude performance improvements in thin-film digital circuits. Sci. Rep. 4, 4295 (2014)
[66]. Lee, S. et al., Subthreshold Schottky-barrier thin-film transistors with ultralow power and high intrinsic gain. Science 354, 302-304 (2016)
[67]. Sangwan, V. K. et al., Self-aligned van der Waals heterojunction diodes and transistors. Nano Lett. 18, 1421-1427 (2018)
[68]. Jiang, C. et al., Printed subthreshold organic transistors operating at high gain and ultralow power. Science 363, 719-723 (2019)
[69]. Zhang, J. et al., Extremely high-gain source-gated transistors. Proc. Natl. Acad. Sci. U.S.A. 116, 4843-4848 (2019).

1. An ohmic-contact-gated transistor (OCGT), comprising:
a bottom gate electrode formed on a substrate;
a first dielectric layer formed on the bottom gate electrode;
a thin film formed of a semiconducting material on the first dielectric layer;
a bottom contact formed on a part of the thin film;
a second dielectric layer conformally grown on the bottom contact to result in a self-aligned dielectric extension from the bottom contact on the thin film; and
a top contact formed on the second dielectric layer on the top of the bottom contact and fully overlapping with the dielectric extension to define a device channel in the thin film under the dielectric extension between the bottom contact and the top contact.

2. The OCGT of claim 1, wherein the substrate comprises an undoped Si wafer.

3. The OCGT of claim 1, wherein the semiconducting material comprises a solution-processed semiconducting material.

4. The OCGT of claim 3, wherein the semiconducting material comprises solution-processed semiconducting single-walled carbon nanotubes (SWCNTs).

5. The OCGT of claim 4, wherein the thin film comprises an SWCNT random network with about 99.9% semiconducting purity.

6. The OCGT of claim 4, wherein the thin film comprises an SWCNT random network with a linear density of about 40 CNTs·μm⁻¹.

7. The OCGT of claim 3, wherein the semiconducting material comprises MoS₂, MoSe₂, WS₂, WSe₂, InSe, GaTe, black phosphorus (BP), or related solution-processed semiconducting materials including organic semiconductor and inorganic metal-oxides.

8. The OCGT of claim 1, wherein the bottom gate electrode, the bottom contact and the top contact are formed of the same conductive material or different conductive materials.

9. The OCGT of claim 8, wherein each of the bottom gate electrode, the bottom contact and the top contact is formed of palladium (Pd), gold (Au), aluminum (Al), titanium (Ti), nickel (Ni), chromium (Cr), other conductive materials including transparent indium tin oxides, or a combination thereof.

10. The OCGT of claim 1, wherein the first dielectric layer and the second dielectric layer comprise a same dielectric material or different dielectric materials.

11. The OCGT of claim 10, wherein each of the first dielectric layer and the second dielectric layer is formed of HfO₂, Al₂O₃, ZrO₂, ZnO, SiO₂, or dielectrics including alumina, hafnia, or zirconia and organic dielectric films grown by conformal molecular layer deposition.

12. The OCGT of claim 11, wherein the second dielectric layer is a thin high-k dielectric layer formed of HfO₂ with a thickness of about 12 nm, k being a dielectric constant, and each of the bottom contact and the top contact is formed of an ohmic contact metal including Pd, for optimal short-channel performance of the SWCNT channel.

13. The OCGT of claim 1, wherein an overlap region of the dielectric extension with the top contact determines a channel length (L) and creates a secondary gate that is shorted to the top contact.

14. The OCGT of claim 1, wherein the OCGT geometry utilizes ohmic contacts with a short-channel length to achieve contact-gating with superior device performance.

15. The OCGT of claim 1, wherein the OCGTs intrinsically mitigate short-channel effects by demonstrating an OCGT-based common-source amplifier.

16. The OCGT of claim 15, wherein a signal gain of the OCGT-based common-source amplifier is quantified by applying a small input signal at the gate input that produces an inverted output signal.

17. The OCGT of claim 1, being used in a common-source amplifier to attain the highest width-normalized output current and length-scaled signal gain to date for solution-processed semiconductors.

18. The OCGT of claim 1, wherein the OCGT is characterized with exceptionally low width-normalized output conductance while maintaining high width-normalized output current levels.

19. The OCGT of claim 1, wherein the OCGT has unprecedented levels of an output current saturation in the short-channel limit for solution-processed semiconductors without compromising output current drive.

20. The OCGT of claim 1, wherein use of ultrahigh purity semiconducting SWCNTs and ultrathin high-k dielectric layers provides improved electrostatic control of the channel, resulting in unipolar p-type transport with a simultaneously high Iₒₙ/I_{off} ratio, high output current, and negligible leakage current despite the short length of the channel.

21. The OCGT of claim 1, wherein the SWCNT OCGTs achieves output current saturation concurrently with high output currents despite the short channel length.

22. A circuit, comprising at least one ohmic-contact-gated transistor (OCGT) according to claim 1.

23. A device, comprising at least one ohmic-contact-gated transistor (OCGT) according to claim 1.

24. A method for fabricating an ohmic-contact-gated transistor (OCGT), comprising:
forming a bottom gate electrode on a substrate;
forming a first dielectric layer on the bottom gate electrode;
forming a thin film of a semiconducting material on the first dielectric layer;
forming a bottom contact on a part of the thin film;
conformally growing a second dielectric layer on the bottom contact to result in a self-aligned dielectric extension from the bottom contact on the thin film; and
forming a top contact on the second dielectric layer on the top of the bottom contact and fully overlapping with the dielectric extension to define a device channel in the thin film under the dielectric extension between the bottom contact and the top contact.

25. The method of claim 24, wherein said forming the thin film is performed by chemical vapor deposition (CVD), mechanical exfoliation, metal-organic chemical vapor deposition (MOCVD), or atomic layer deposition (ALD).

26. The method of claim 24, wherein the semiconducting material comprises a solution-processed semiconducting material.

27. The method of claim 26, wherein the semiconducting material comprises solution-processed semiconducting single-walled carbon nanotubes (SWCNTs).

28. The method of claim 27, wherein the thin film comprises an SWCNT random network with about 99.9% semiconducting purity.

29. The method of claim 27, wherein the thin film comprises an SWCNT random network with a linear density of about 40 CNTs·μm⁻¹.

30. The method of claim 26, wherein the semiconducting material comprises MoS₂, MoSe₂, WS₂, WSe₂, InSe, GaTe, black phosphorus (BP), or related solution-processed semiconducting materials including organic semiconductor and inorganic metal-oxides.

31. The method of claim 24, wherein said forming the first dielectric layer is performed by photolithography and directional metal evaporation.

32. The method of claim 24, wherein said growing the second dielectric layer is performed with an undercut profile of negative photoresist combined with directional metal evaporation and conformal atomic layer deposition (ALD) of a dielectric oxide resulting in the self-aligned dielectric extension.

33. The method of claim 24, wherein the top contact electrode is patterned using photolithography and directional metal evaporation such that it fully overlaps the dielectric extending from the bottom contact.

34. The method of claim 24, wherein the bottom gate electrode, the bottom contact and the top contact are formed of the same conductive material or different conductive materials.

35. The method of claim 34, wherein each of the bottom gate electrode, the bottom contact and the top contact is formed of palladium (Pd), gold (Au), aluminum (Al), titanium (Ti), nickel (Ni), chromium (Cr), or other conductive materials including transparent indium tin oxide.

36. The method of claim 24, wherein the first dielectric layer and the second dielectric layer comprise a same dielectric material or different dielectric materials.

37. The method of claim 36, wherein each of the first dielectric layer and the second dielectric layer is formed of HfO₂, Al₂O₃, ZrO₂, ZnO, SiO₂, or dielectrics including alumina, hafnia, or zirconia and organic dielectric films grown by conformal molecular layer deposition.
